(19) United States
(12) Patent Application Publication
(10) Pub. No.: US 2025/0287506 A1
(43) Pub. Date: Sep. 11, 2025

(54) ELECTRONIC DEVICE AND ELECTRONIC APPARATUS

(71) Applicant: PanelSemi Corporation, New Taipei City (TW)

(72) Inventor: Chin-Tang LI, New Taipei City (TW)

(21) Appl. No.: 19/073,230

(22) Filed: Mar. 7, 2025

Related U.S. Application Data
(60) Provisional application No. 63/562,384, filed on Mar. 7, 2024.

(51) Int. Cl. H05K 1/18; H05K 1/11; H05K 1/14; H05K 3/00

(52) U.S. Cl. CPC H05K 1/181; H05K 1/113; H05K 1/115; H05K 1/144; H05K 3/0026; H05K 2201/0939; H05K 2201/094; H05K 2201/09609; H05K 2201/09618; H05K 2201/10378; H05K 2201/10522

(57) ABSTRACT

An electronic device includes a substrate, a trace layer, through holes, conductive members, functional elements and a protection member. The substrate defines a first surface and a second surface. The trace layer is arranged on the first surface. The through holes communicate with the first surface and the second surface, and the through hole defines a first opening approaching the first surface and a second opening approaching the second surface. The conductive members are electrically connected to the trace layer and arranged in the through holes respectively. At least one conductive member defines a revealed portion protruding from the second opening of the corresponding through hole. The functional elements are arranged on the first surface and electrically connected with one or ones of the conductive members through the trace layer. The protection member is arranged on the first surface and covers one or ones of the functional elements.

### CROSS REFERENCE TO RELATED APPLICATIONS

This Non-provisional application claims priority to U.S. provisional patent application with Ser. No. 63/562,384 filed on Mar. 7, 2024. This and all other extrinsic materials discussed herein are incorporated by reference in their entirety.

### BACKGROUND

### Technology Field

The disclosure relates to an electronic device.

### Description of Related Art

A problem of conventional bonding approaches lacks mechanical strength, and there should be a solution thereto. Specifically, the conventional electronic devices and methods often faced a series of limitations. A notable shortcoming was the limited contact area with solder, which typically involved only top surface contact without the benefits of circumferential side contact. This resulted in a compromised mechanical strength, with a decreased ability to withstand push-pull forces, thereby making the devices more susceptible to physical connection failures. Furthermore, the inadequate contact area frequently led to higher contact resistance, which could diminish the electrical efficiency and reliability of the device. These constraints often rendered traditional designs less capable of meeting the growing demands for durable and high-performing electronic components.

### SUMMARY

One or more exemplary embodiments of this disclosure are to provide an electronic device and an electronic apparatus having the advantage of offering considerable improvements, which includes an increase contact area with solder, facilitated by the implementation of circumferential side contacts, so as to not only enhance mechanical strength, as evidenced by the increased push-pull force, but also to reduce contact resistance. The outcome is a device and apparatus that deliver robust performance and reliability.

An electronic device comprises a substrate, a trace layer, a plurality of through holes, a plurality of conductive members, a plurality of functional elements, and a protection member. The substrate defines a first surface and a second surface opposite to each other. The trace layer is arranged on the first surface of the substrate. The through holes communicate with the first and the second surfaces of the substrate, and at least one of the through holes defines a first opening approaching the first surface of the substrate and a second opening approaching the second surface of the substrate, and defines a through-hole volume formed thereof. The first opening of one of the through holes is covered by partial of the trace layer. The conductive members electrically connect to the trace layer and arranged in the through holes respectively, and at least one of the conductive members defines a conductive-member volume formed thereof. The conductive-member volume of one of the conductive members is greater than the through-hole volume in a corresponding one of the through holes. The functional elements are arranged on the first surface of the substrate and electrically connected with one or ones of the conductive members through the trace layer. The protection member is arranged on the first surface of the substrate and covers one or ones of the functional elements.

This invention also provides another electronic device, which comprises a substrate, a trace layer, a plurality of through holes, a plurality of conductive members, a plurality of functional elements, and a protection member. The substrate defines a first surface and a second surface opposite to each other. The trace layer is arranged on the first surface of the substrate. The through holes communicate with the first and the second surfaces of the substrate, and at least one of the through holes defines a first opening approaching the first surface of the substrate and a second opening approaching the second surface of the substrate. The conductive members electrically connect to the trace layer and are arranged in the through holes respectively. At least one of the conductive members defines a revealed portion protruding from the second opening of a corresponding one of the through holes. The functional elements are arranged on the first surface of the substrate and electrically connected with one or ones of the conductive members through the trace layer. The protection member is arranged on the first surface of the substrate and covers one or ones of the functional elements.

This invention also provides another electronic device, which includes a substrate, a trace layer, a plurality of through holes, a plurality of conductive members, a plurality of functional elements, and a protection member. The substrate defines a first surface and a second surface opposite to each other. The trace layer is arranged on the first surface of the substrate. The through holes communicate with the first and the second surfaces of the substrate, and at least one of the through holes defines a first opening approaching the first surface of the substrate and a second opening approaching the second surface of the substrate. The conductive members electrically connect to the trace layer and are arranged in the through holes respectively. At least one of the conductive members defines a revealed portion protruding from the second opening of a corresponding one of the through holes. The functional elements are arranged on the first surface of the substrate and electrically connected with one or ones of the conductive members through the trace layer. The protection member is arranged on the first surface of the substrate and covers one or ones of the functional elements. A ratio of a measured area of the first opening to a measured area of the revealed portion of the conductive member arranged therein is no less than 1/4.

This invention also provides another electronic device defines a total thickness and comprises a substrate, a trace layer, a plurality of through holes, a plurality of conductive members, a plurality of functional elements, and a protection member. The substrate defines a first surface and a second surface opposite to each other, and a thickness thereof. The trace layer is arranged on the first surface of the substrate. The through holes communicate with the first and the second surfaces of the substrate, and at least one of the through holes defines a first opening approaching the first surface of the substrate and a second opening approaching the second surface of the substrate. The conductive members electrically connect to the trace layer and arranged in the through holes respectively, and at least one of the conductive members defines a revealed portion protruding from the second opening of the corresponding through hole. The functional elements are arranged on the first surface of the substrate and electrically connected with one or ones of the conductive members through the trace layer. The protection member is arranged on the first surface of the substrate and covers one or ones of the functional elements. The thickness of the substrate is no greater than 50 μm.

The above-mentioned electronic devices, also include the following features:

In one embodiment, the substrate defines a thickness no greater than 100 μm.

In one embodiment, the thickness of the substrate is no greater than 50 μm.

In one embodiment, the electronic device further defines a total thickness thereof, and the substrate defines a thickness no greater than half of the total thickness.

In one embodiment, the electronic device further defines a total thickness thereof, and the substrate defines a thickness no greater than one-third of the total thickness.

In one embodiment, the substrate is resilient.

In one embodiment, the substrate is a composite substrate.

In one embodiment, at least partial of the trace layer defines a trace space no greater than 50 μm.

In one embodiment, the trace space of at least partial of the trace layer is no greater than 30 μm.

In one embodiment, the trace space of at least partial of the trace layer is no greater than 15 μm.

In one embodiment, at least partial of the trace layer defines a thickness no greater than 20 μm.

In one embodiment, the thickness of at least partial of the trace layer is no greater than 10 μm.

In one embodiment, the trace layer is made of a sputtering process.

In one embodiment, an exterior face of a corresponding one of the conductive members defines an average roughness Ra no less than 0.5 μm.

In one embodiment, the conductive member includes one or more conductive materials having a volume percentage no less than 70% of the conductive-member volume thereof.

In one embodiment, within a corresponding one of the through holes, a measured area of the first opening is no greater than a measured area of the second opening.

In one embodiment, within a corresponding one of the through holes, the conductive member defines a revealed portion protruding from the second opening of the through hole.

In one embodiment, the conductive member includes one or more conductive materials in a consistent manner in a direction parallel to the substrate.

In one embodiment, the substrate includes a base sheet and a bonding sheet stacked on the base sheet, and the first surface is a surface of the base sheet and the second surface is a surface of the bonding sheet.

In one embodiment, the conductive member further defines a concealed portion in conjunction with the revealed portion, the concealed portion locates in one of the through holes, the conductive member includes one or more kinds of conductive material, and the one or more kinds of conductive material of the revealed portion are consistent with the one or more kinds of conductive material of a concealed portion.

In one embodiment, the revealed portion of the conductive member defines a contact region where the revealed portion overlaid on the second surface of the substrate, the contact region of the revealed portion defines a lateral measurement in a direction parallel to the second surface of the substrate, and the lateral measurement of the contact region is at most 10 μm larger than a radius of the second opening of the corresponding through hole which the conductive member is arranged in.

In one embodiment, a height of the revealed portion of the conductive member is no less than 5 μm in a direction perpendicular to the substrate.

In one embodiment, a height of the revealed portion of the conductive member in a direction perpendicular to the substrate is no less than 10% of a thickness of the substrate.

In one embodiment, the revealed portion of the conductive member defines a tip.

In one embodiment, the revealed portion of the conductive member defines a crater.

In one embodiment, the thickness of the substrate is no greater than half of the total thickness.

An electronic apparatus comprises a circuit board including a circuit trace layer thereof, and at least one of the electronic devices as mentioned above electrically connecting the circuit trace layer of the circuit board, wherein one of the functional elements electrically connects with the circuit trace layer through the connections between ones of the conductive members and the circuit trace layer.

A manufacturing method for an electronic device comprises steps of: preparing a substrate provided with a trace layer and one or more functional elements thereon; forming a protection member to cover the functional elements; and forming a plurality of through holes and disposing a plurality of conductive members in the through holes, in which at least one of the conductive members defines a revealed portion protruding from the second opening of the corresponding through hole.

A manufacturing method for an electronic apparatus comprises steps of: preparing a circuit board including a circuit trace layer thereof; and electrically connecting an electronic device to the circuit trace layer of the circuit board, wherein one of the functional elements electrically connect with the circuit trace layer through the connections between ones of the conductive members and the circuit trace layer.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a cross-section profile showing an electronic device according to an embodiment of this disclosure;

FIG. 1A is a partial enlarged view of the circle shown in FIG. 1;

FIG. 1B shows another aspect of the conductive member in this invention;

FIG. 2 is a top view of the electronic device of FIG. 1;

FIG. 3 is a cross-section profile showing an electronic device according to another embodiment of this disclosure;

FIG. 4 is a cross-section profile showing an electronic device according to another embodiment of this disclosure;

FIGS. 5A to 5I are cross-section profiles showing the manufacturing of the electronic device of FIG. 1;

FIG. 6A shows the manufacturing of an electronic apparatus according to an embodiment of this disclosure; and

FIG. 6B is a cross-section profile showing the manufactured electronic apparatus according to the embodiment of this disclosure.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

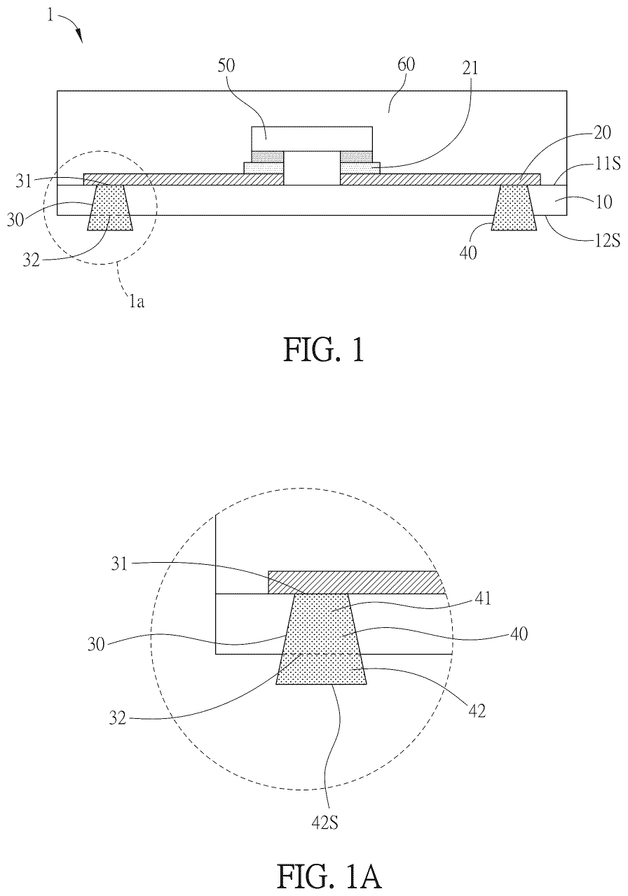

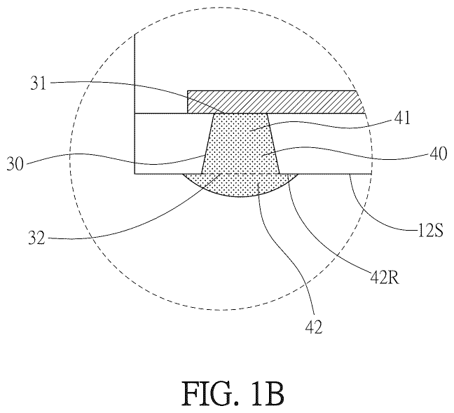

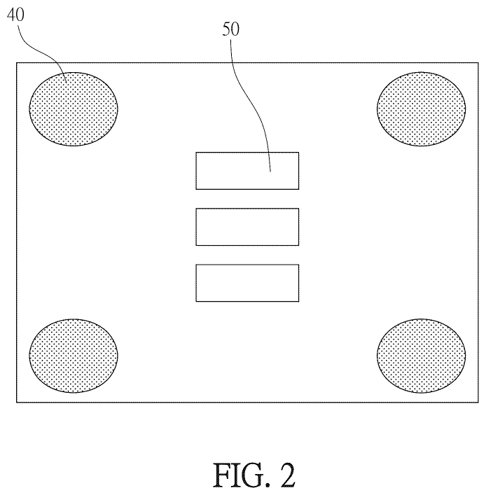

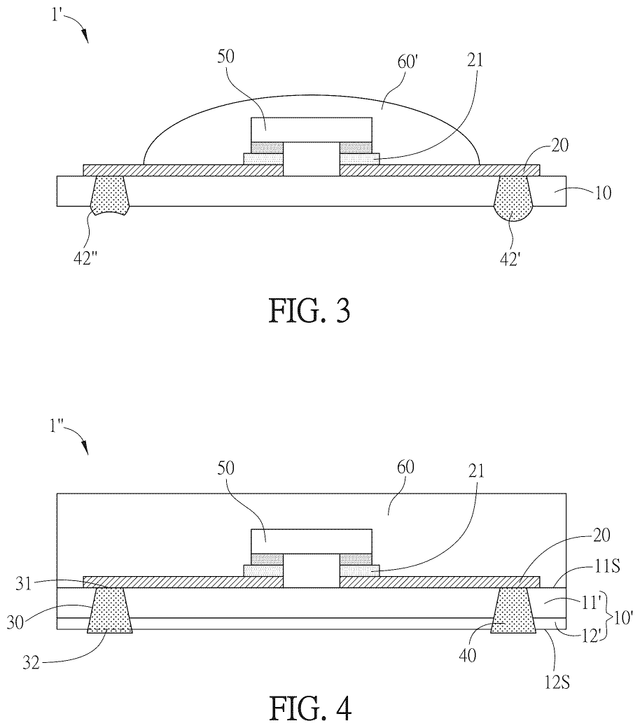

FIG. 1 is a cross-section profile showing an electronic device 1 including a substrate 10, a trace layer 20, a plurality of through holes 30, a plurality of conductive members 40, a plurality of functional elements 50, and a protection member 60. Referring to FIG. 1 in view of FIG. 1A and FIG. 2, wherein FIG. 1A is a partial enlarged view of the circle 1a shown in FIG. 1, FIG. 2 is a top view of the electronic device 1. The substrate 10 defines a first surface 11S and a second surface 12S opposite to each other. The trace layer 20 is arranged on the first surface 11S of the substrate 10. The through holes 30 communicate with the first surface 11S and the second surface 12S of the substrate 10, and at least one of the through holes 30 defines a first opening 31 approaching the first surface 11S of the substrate 10 and a second opening 32 approaching the second surface 12S of the substrate 10. The through hole 30 defines a through-hole volume formed thereof. The first opening 31 of one of the through holes 30 is covered by partial of the trace layer 20, which means that the first opening 31 of one of the through holes 30 can be sealed by partial of the trace layer 20 or a bonding pad extended from the trace layer 20. The conductive members 40 electrically connect to the trace layer 20 and are arranged in the through holes 30 respectively, and at least one of the conductive members 40 defines a conductive-member volume formed thereof. The conductive-member volume of one of the conductive members 40 is greater than the through-hole volume in a corresponding one of the through holes 30. The functional elements 50 are arranged on the first surface 11S of the substrate 10 and electrically connected with one or ones of the conductive members 40 through the trace layer 20. The protection member 60 is arranged on the first surface 11S of the substrate 10 and covers one or ones of the functional elements 50.

In one case, the substrate 10 defines a thickness no greater than 100 μm. In another case, the substrate 10 defines a thickness no greater than 50 μm. In another point of view, the thickness of the substrate 10 may be defined in another way, which is no greater than half of a total thickness defined by the integrity of the electronic device 1. In another case, the thickness of the substrate 10 may be no greater than one-third of the total thickness of the electronic device 1.

In one case, the trace layer 20 is formed by a thin copper process (e.g. a sputtering process (thin-film process)), an evaporation process, an electroplating process, an electroless process, or a foiling copper process (e.g. with a rolled copper foil, an annealed copper foil, a rolled annealed copper foil (RA copper foil)). In one case, at least partial of the trace layer 20 defines a trace space no greater than 50 μm. In another case, the trace space of at least partial of the trace layer 20 is no greater than 30 μm. In another case, the trace space of at least partial of the trace layer 20 is no greater than 15 μm. In one case, the functional element 50 contacts the trace layer 20 through a bonding pad 21, which is in consideration of the partial of the trace layer 20. In one case, at least partial of the trace layer 20 defines a thickness no greater than 20 μm. In another case, the thickness of at least partial of the trace layer 20 is no greater than 10 μm.

In one case, within a corresponding one of the through holes 30, a measured area of the first opening 31 is no greater than a measured area of the second opening 32.

In one case, one or ones of the functional elements 50 are functional chips. In another case, one or ones of the functional elements 50 may be functional packages.

In one case, the conductive member 40 includes one or more conductive materials, such as, for example but not limited to, copper or silver, no less than 70% (in volume percentage) thereof. In one case, the conductive member 40 includes one or more conductive materials, the one or more conductive materials is/are distributed in a consistent manner of a plurality of the sections of the conductive member 40 parallel to the first surface 11S of the substrate 10.

In one case, at least one of the conductive members 40 defines a concealed portion 41 locating in the corresponding through hole 30 and a revealed portion 42 protruding from the second opening 32 of the corresponding through hole 30, and the concealed portion 41 is in conjunction with the revealed portion 42. The conductive member 40 includes one or more kinds of conductive materials, and the one or more kinds of conductive materials of the revealed portion 42 are consistent with those of the concealed portion 41 in the direction parallel to the substrate 10. In one case as shown in FIG. 1B, the revealed portion 42 defines a contact region 42R where the revealed portion 42 overlaid on the second surface 12S of the substrate 10, and the contact region 42R of the revealed portion 42 defines a lateral measurement in the direction parallel to the second surface 12S of the substrate 10. The lateral measurement of the contact region 42R is at most 10 μm larger than a radius of the second opening 32 of the corresponding through hole 30 in which the conductive member 40 is arranged.

In one case, a height of the revealed portion 42 of the conductive member 40 is no less than 5 μm in a direction perpendicular to the substrate 10. In another case, a height of the revealed portion 42 of the conductive member 40 in a direction perpendicular to the substrate 10 is no less than 10% of the thickness of the substrate 10.

Referred in FIG. 1A, at least one of the conductive members 40 defines a revealed portion 42 protruding from the second opening 32 of a corresponding one of the through holes 30 and exposed/revealed or may be further exposed out of the second surface 12S of the substrate 10, and a concealed portion 41 in conjunction with the revealed portion 42 received within the corresponding one of the through holes 30. The revealed portion 42 defines an exterior face 42S thereof, which is non-flatted or uneven, and an average roughness Ra of the exterior face 42S. The average roughness Ra of the exterior face 42S is no less than 0.5 μm.

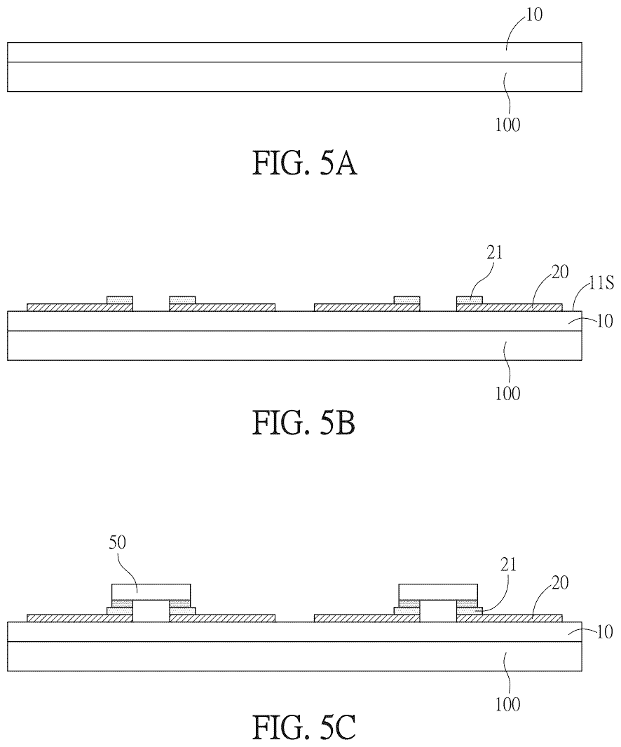

Referred in FIG. 3, in an electronic device 1′ of another embodiment, a protection member 60′ in another shape, such as a dome shape, is illustrated. The conductive members 40′ and 40″ define a revealed portion 42′ and a revealed portion 42″, respectively. The revealed portion 42′ is provided with a tip at a distal end thereof, and the revealed portion 42″ is provided with a crater at a distal end thereof. As we may know, the distal end of the revealed portion is provided with the exterior face of the average roughness Ra.

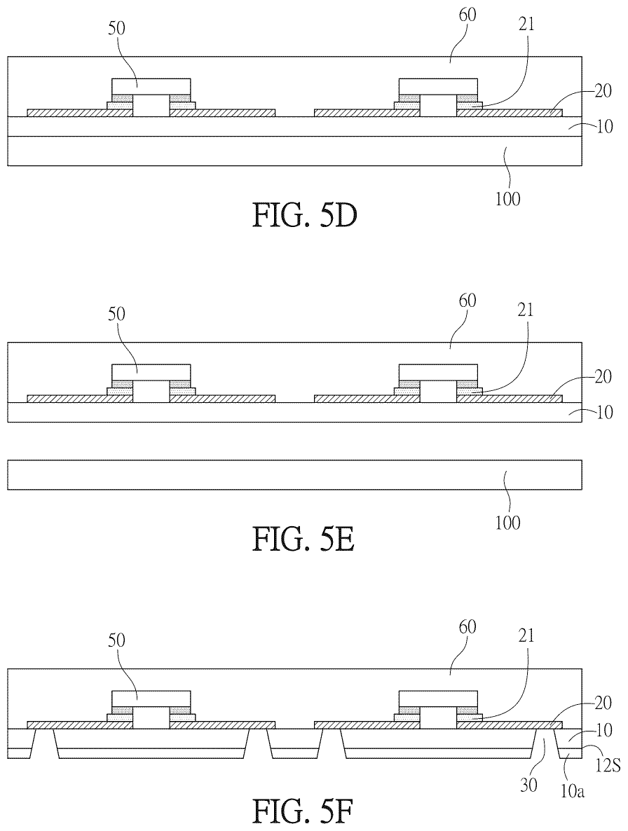

Referred in FIG. 4, in an electronic device 1″ of another embodiment, a substrate 10′ includes a base sheet 11′ and a bonding sheet 12′ stacked thereto, and the first surface 11S is the top surface of the base sheet 11′ and the second surface 12S is the bottom surface of the bonding sheet 12′. To be noted, the base sheet 11′ is generally considered as a substrate, which is of single or multiple layers or of same or different materials, and the bonding sheet 12′ here could be a substrate ready for bonding to the base sheet 11′, or an adhesion layer covering the base sheet 11′. In the case that the bonding sheet 12′ is taken as a substrate, the substrate 10′ is substantially taken as a composite substrate, and the bonding sheet 12′ may be also of single or multiple layers or of same or different materials. In the case of the electronic device 1, the thickness of the substrate 10 no greater than one-third of the total thickness of the electronic device 1 is applied thereto. The base sheet 11′ and the bonding sheet 12′ may be made of different materials, but not limited thereto. The substrate 10′ in another case may further include one or more substrates, other than the base sheet 11′ and the bonding sheet 12′. In this case, the additional substrate(s) may be piled between the base sheet 11′ and the bonding sheet 12′.

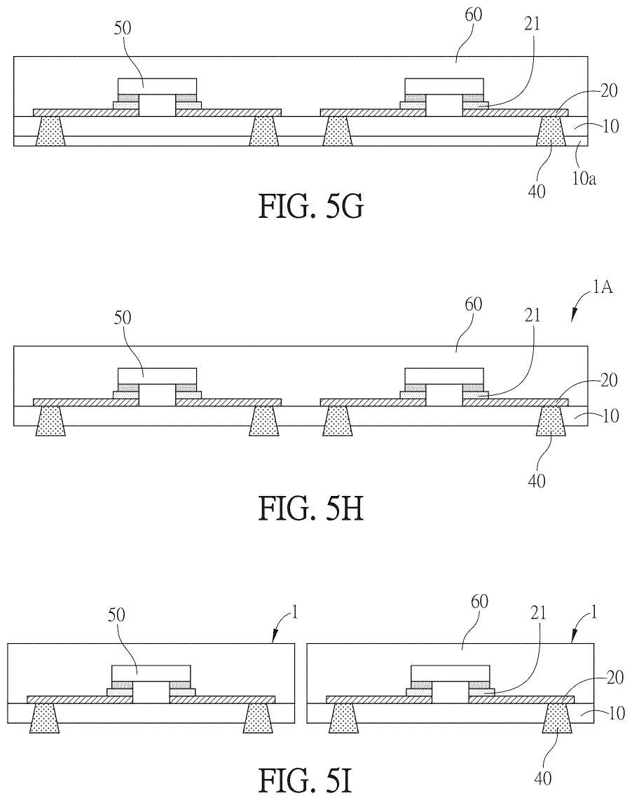

Here are details for manufacturing the electronic device 1 according to the disclosure referred in FIGS. 5A to 5I.

Here we take a substrate 10 being resilient as an example in FIG. 5A in this case, and the substrate 10 is arranged on a rigid board 100 in advance.

Referred in FIG. 5B in this case, a trace layer 20 is disposed onto the substrate 10 and includes one or more bonding pads 21, which are in consideration of the partial of the trace layer 20.

FIG. 5C shows one or more functional elements 50 arranged on the first surface 11S of the substrate 10 and electrically connected with the trace layer 20 and may further through one or ones of the bonding pads 21.

FIG. 5D depicts a protection member 60 arranged on the first surface 11S of the substrate 10 and covering one or ones of the functional elements 50.

Referred in FIG. 5E, the substrate 10 and the rigid board 100 are separated from each other.

Referred in FIG. 5F, an additional film 10a is attached onto the second surface 12S of the substrate 10, and one or more through holes 30 are formed on the substrate 10 from the additional film 10a by, for example, a laser process.

FIG. 5G depicts a plurality of conductive members 40 arranged in through holes 30 respectively.

Referred in FIG. 5H, the additional film 10a is separated from the substrate 10, and a portion of the conductive members 40 can protrude from the second surface 12S of the substrate 10 so as to form the revealed portion. Here we have a temporary electronic device 1A.

Referred in FIG. 5I, resizing the temporary electronic device 1A properly and forming one or more electronic device 1 are done.

In one case, the substrate 10 may be not a resilient substrate, and in FIG. 5A to 5E, the rigid board 100 and some steps can be omitted.

In one case, the substrate 10 can be applied as a single or multiple layer substrate. For example, the substrate 10′, which is a multiple layer substrate, can be applied in the manufacturing of FIGS. 5A to 5I.

In one case, the additional film 10a can be treated as the bonding sheet 12′ as mentioned in FIG. 4. To be noted, the conductive members 40 here is still protruding from the second surface 12S of the substrate 10.

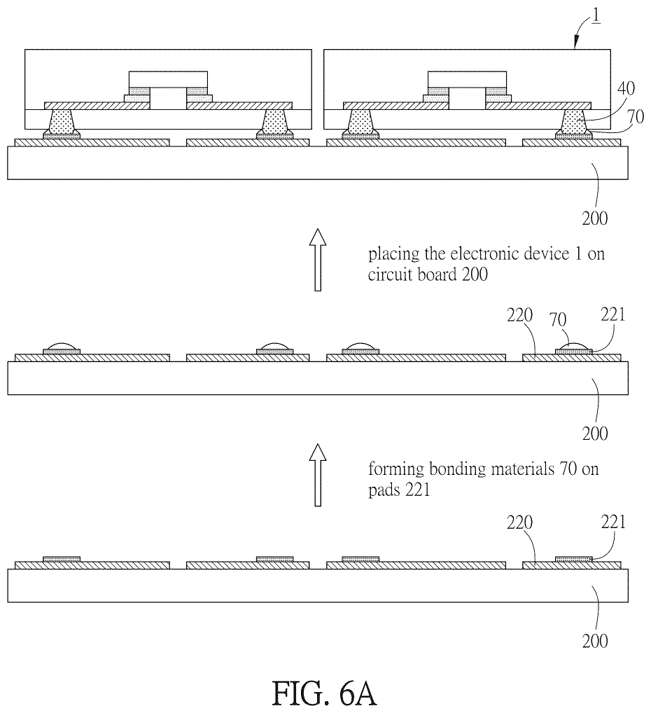

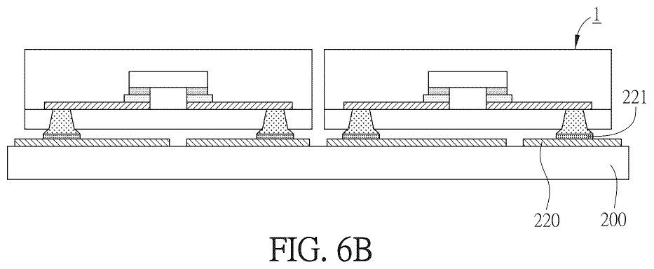

Now the electronic devices 1 are ready, and please see FIG. 6A, there are one or more circuit boards 200 provided, in which the circuit board 200 is provided with a circuit trace layer 220 and formed with bonding materials 70 on pads 221 of the circuit trace layer 220. To be noted, the pads 221 are taken as partial of the circuit trace layer 220. One or ones of the electronic devices 1 are placed on the circuit board 200 and the conductive members 40 are arranged on the bonding materials 70 which are arranged on the pads 221 of the circuit trace layer 220 in advance. The bonding materials 70 may be achieved by soldering process.

Referred in FIG. 6B, the conductive members 40 are electrically connected with the pads 221 of the circuit trace layer 220 by converting the bonding materials 70 therewith to form an eutectic bonding. This step may be achieved by heating or further with increasing pressure.

To conclude the steps of the manufacturing approach, there should be at least stages mentioned below, such as stage 1 of preparing the substrate 10 provided with the trace layer 20 and the functional elements 50 thereon; stage 2 of forming the protection member 60 to cover the functional elements 50; and stage 3 of forming the through holes 30 and the conductive members 40 arranged therein and revealed outwardly. By stages 1 to 3, the electronic device 1 is accomplished.

For further assembly, stage 4 is to integrate the steps in FIGS. 6A and 6B for bonding the electronic device 1 onto the circuit board 200 to accomplish an electronic apparatus.

To summarize the disclosure, the electronic device and a method associated thereby advantage of offering considerable improvements, which includes an increased contact area with solder, facilitated by the implementation of circumferential side contacts, so as to enhance mechanical strength. To be noted, it is reasonable to read all features in different combinations in the description likely of claim construction.

Some embodiments of this disclosure are summarized hereinbelow.

An electronic device comprises: a substrate defining a first surface and a second surface opposite to each other; a trace layer arranged on the first surface of the substrate; a plurality of through holes communicating with the first and the second surfaces of the substrate, and each of the through holes defining a first opening and a second opening respectively approaching the first and the second surfaces of the substrate, and a through-hole volume formed thereof; wherein the first opening of one of the through holes is covered by partial of the trace layer; a plurality of conductive members electrically connected to the trace layer and arranged in the through holes in a respective manner, and each of the conductive members defining a conductive-member volume formed thereof; wherein the conductive-member volume of one of the conductive members is greater than the through-hole volume in a corresponding one of the through holes; a plurality of functional elements disposed on the first surface of the substrate and electrically connected with one or ones of the conductive members through the trace layer; and a protection member disposed on the first surface of the substrate and covering one or ones of the functional elements.

Another electronic device is provided, which comprises: a substrate defining a first surface and a second surface opposite to each other; a trace layer arranged on the first surface of the substrate; a plurality of through holes communicating with the first and the second surfaces of the substrate, and at least one of the through holes defines a first opening approaching the first surface of the substrate and a second opening approaching the second surface of the substrate; a plurality of conductive members electrically connected to the trace layer and arranged in the through holes respectively, and at least one of the conductive members defines a revealed portion protruding from the second opening of a corresponding one of the through holes; a plurality of functional elements arranged on the first surface of the substrate and electrically connected with one or ones of the conductive members through the trace layer; and a protection member arranged on the first surface of the substrate and covering one or ones of the functional elements.

Another electronic device is provided, which comprises a substrate defining a first surface and a second surface opposite to each other; a trace layer arranged on the first surface of the substrate; a plurality of through holes communicating with the first and the second surfaces of the substrate, and at least one of the through holes defines a first opening approaching the first surface of the substrate and a second opening approaching the second surface of the substrate; a plurality of conductive members electrically connected to the trace layer and arranged in the through holes respectively, and at least one of the conductive members defines a revealed portion protruding from and exposed out of the second opening of one corresponding through hole; a plurality of functional elements arranged on the first surface of the substrate and electrically connected with one or ones of the conductive members through the trace layer; and a protection member arranged on the first surface of the substrate and covering one or ones of the functional elements; wherein a ratio of a measured area of the first opening to a measured area of the revealed portion of the conductive member arranged therein is no less than 1/4.

The electronic device is provided, which defines a total thickness, comprises: a substrate defining a first surface and a second surface opposite to each other, and a thickness thereof; a trace layer arranged on the first surface of the substrate; a plurality of through holes communicating with the first and the second surfaces of the substrate, wherein at least one of the through holes defines a first opening approaching the first surface of the substrate and a second opening approaching the second surface of the substrate; a plurality of conductive members electrically connected to the trace layer and arranged in the through holes respectively, wherein at least one of the conductive members defines a revealed portion exposed of the second surface of the substrate; a plurality of functional elements arranged on the first surface of the substrate and electrically connected with one or ones of the conductive members through the trace layer; and a protection member arranged on the first surface of the substrate and covering one or ones of the functional elements; wherein the thickness of the substrate is no greater than 50 μm.

The above-mentioned electronic devices also include the following features:

In one embodiment, the substrate defines a thickness no greater than 100 μm.

In one embodiment, the thickness of the substrate is no greater than 50 μm.

In one embodiment, the electronic device further defines a total thickness thereof, and the substrate defines a thickness no greater than half of the total thickness.

In one embodiment, the substrate is resilient.

In one embodiment, the substrate is a composite substrate.

In one embodiment, at least partial of the trace layer defines a trace space no greater than 50 μm.

In one embodiment, the trace space of at least partial of the trace layer is no greater than 30 μm.

In one embodiment, the trace space of at least partial of the trace layer is no greater than 15 μm.

In one embodiment, at least partial of the trace layer defines a thickness no greater than 20 μm.

In one embodiment, the thickness of at least partial of the trace layer is no greater than 10 μm.

In one embodiment, the trace layer is made of a sputtering process.

In one embodiment, a corresponding one of the conductive members defines an average roughness Ra no less than 0.5 μm at an exterior face thereof.

In one embodiment, the conductive member includes one or more conductive materials occupied no less than 70% of the conductive-member volume thereof.

In one embodiment, within a corresponding one of the through holes, a measured area of the first opening is no greater than a measured area of the second opening.

In one embodiment, within a corresponding one of the through holes, the conductive member defines a revealed portion protruding from the second opening of the through hole and exposed out of the second surface of the substrate.

In one embodiment, the conductive member includes one or more conductive materials in a consistent manner in a direction parallel with the substrate.

In one embodiment, the electronic device further defines a total thickness thereof, and the substrate defines a thickness no greater than half of the total thickness of the electronic device.

In one embodiment, the substrate includes a base sheet and a bonding sheet stacked on the base sheet, and the first surface is a surface of the base sheet and the second surface is a surface of the bonding sheet.

In one embodiment, the conductive member further defines a concealed portion in conjunction with the revealed portion, the concealed portion locates in one of the through holes, the conductive member includes one or more kinds of conductive material, and the one or more kinds of conductive material of the revealed portion are consistent with those of the concealed portion.

In one embodiment, the revealed portion of the conductive member defines a contact region where the revealed portion overlaid on the second surface of the substrate, the contact region of the revealed portion defines a lateral measurement in a direction parallel to the second surface of the substrate, and the lateral measurement of the contact region is at most 10 μm larger than a radius of the second opening of the corresponding through hole which the conductive member is arranged in.

In one embodiment, a height of the revealed portion of a corresponding one of the conductive members is no less than 5 μm in a direction perpendicular to the substrate.

In one embodiment, a height of the revealed portion of the conductive member in a direction perpendicular to the substrate is no less than 10% of a thickness of the substrate.

In one embodiment, the revealed portion of the conductive member defines a tip or a crater.

This invention also provides an electronic apparatus comprises: a circuit board including a circuit trace layer thereof, and at least one of the electronic device as mentioned above electrically connecting the circuit trace layer of the circuit board, wherein one of the functional elements electrically connects with the circuit trace layer through the connections between ones of the conductive members and the circuit trace layer.

A manufacturing method for an electronic device as mentioned above comprises: preparing a substrate provided with a trace layer and one or more functional elements thereon; forming a protection member to cover the functional elements; and forming a plurality of through holes and arranging a plurality of conductive members in the through holes, in which one of the conductive members reveals outwardly of the substrate.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device, comprising:
a substrate defining a first surface and a second surface opposite to each other;
a trace layer arranged on the first surface of the substrate;
a plurality of through holes communicating with the first surface and the second surface of the substrate, wherein at least one of the through holes defines a first opening approaching the first surface of the substrate and a second opening approaching the second surface of the substrate;
a plurality of conductive members electrically connected to the trace layer and arranged in the through holes respectively, wherein at least one of the conductive members defines a revealed portion protruding from the second opening of a corresponding one of the through holes;
a plurality of functional elements arranged on the first surface of the substrate and electrically connected with one or ones of the conductive members through the trace layer; and
a protection member arranged on the first surface of the substrate and covering one or ones of the functional elements.

2. The electronic device as claimed in claim 1, wherein the substrate defines a thickness no greater than 100 μm.

3. The electronic device as claimed in claim 1, wherein the electronic device further defines a total thickness thereof, and the substrate defines a thickness no greater than half of the total thickness of the electronic device.

4. The electronic device as claimed in claim 1, wherein at least partial of the trace layer defines a trace space no greater than 50 μm.

5. The electronic device as claimed in claim 1, wherein at least partial of the trace layer defines a thickness no greater than 20 μm.

6. The electronic device as claimed in claim 1, wherein within a corresponding one of the conductive members, an exterior face of the revealed portion defines an average roughness no less than 0.5 μm.

7. The electronic device as claimed in claim 1, wherein the conductive member includes one or more conductive materials having a volume percentage no less than 70% of a volume of the conductive member.

8. The electronic device as claimed in claim 1, wherein the substrate comprises a base sheet and a bonding sheet stacked on the base sheet, and the first surface is a surface of the base sheet and the second surface is a surface of the bonding sheet.

9. The electronic device as claimed in claim 1, wherein the conductive member further defines a concealed portion in conjunction with the revealed portion, the concealed portion locates in one of the through holes, the conductive member comprises one or more kinds of conductive material, and the one or more kinds of conductive material of the revealed portion are consistent with the one or more kinds of conductive materials of the concealed portion.

10. The electronic device as claimed in claim 1, wherein the revealed portion of the conductive member defines a contact region where the revealed portion overlaid on the second surface of the substrate, the contact region of the revealed portion defines a lateral measurement in a direction parallel to the second surface of the substrate, and the lateral measurement of the contact region is at most 10 μm larger than a radius of the second opening of the corresponding through hole which the conductive member is arranged in.

11. The electronic device as claimed in claim 1, wherein a height of the revealed portion of the conductive member in a direction perpendicular to the substrate is no less than 10% of a thickness of the substrate.

12. The electronic device as claimed in claim 1, wherein the revealed portion of the conductive member defines a tip or a crater.

13. An electronic device, comprising:
a substrate defining a first surface and a second surface opposite to each other;
a trace layer arranged on the first surface of the substrate;
a plurality of through holes communicating with the first surface and the second surface of the substrate, wherein at least one of the through holes defines a first opening approaching the first surface of the substrate and a second opening approaching the second surface of the substrate;
a plurality of conductive members electrically connected to the trace layer and arranged in the through holes respectively, wherein at least one of the conductive members defines a revealed portion protruding from the second opening of a corresponding one of the through holes;
a plurality of functional elements arranged on the first surface of the substrate and electrically connected with one or ones of the conductive members through the trace layer; and
a protection member arranged on the first surface of the substrate and covering one or ones of the functional elements;
wherein, a ratio of a measured area of the first opening to a measured area of the revealed portion of the conductive member arranged therein is no less than 1/4.

14. The electronic device as claimed in claim 13, wherein the substrate defines a thickness no greater than 100 μm.

15. The electronic device as claimed in claim 13, wherein the electronic device further defines a total thickness thereof, and the substrate defines a thickness no greater than half of the total thickness of the electronic device.

16. The electronic device as claimed in claim 13, wherein at least partial of the trace layer defines a trace space no greater than 50 μm.

17. The electronic device as claimed in claim 13, wherein an exterior face of the revealed portion of one or ones of the conductive members defines an average roughness no less than 0.5 μm.

18. The electronic device as claimed in claim 13, wherein the conductive member includes one or more conductive materials having a volume percentage no less than 70% of a volume of the conductive member.

19. The electronic device as claimed in claim 13, wherein the conductive member further defines a concealed portion in conjunction with the revealed portion, the concealed portion locates in one of the through holes, the conductive member comprises one or more kinds of conductive materials, and the one or more kinds of conductive materials of the revealed portion are consistent with the one or more kinds of conductive materials of the concealed portion.

20. The electronic device as claimed in claim 13, wherein the substrate comprises a base sheet and a bonding sheet stacked on the base sheet, and the first surface is a surface of the base sheet and the second surface is a surface of the bonding sheet.

21. The electronic device as claimed in claim 13, wherein the revealed portion defines a contact region where the revealed portion overlaid on the second surface of the substrate in a direction parallel to the second surface of the substrate, and a lateral measurement of the contact region is at most 10 μm larger than a radius of the second opening of the corresponding through hole which the conductive member is arranged in.

22. An electronic apparatus comprising:
a circuit board comprising a circuit trace layer, and
an electronic device electrically connecting the circuit trace layer of the circuit board, wherein
the electronic device comprises:
a substrate defining a first surface and a second surface opposite to each other;
a trace layer arranged on the first surface of the substrate;
a plurality of through holes communicating with the first surface and the second surface of the substrate, wherein at least one of the through holes defines a first opening approaching the first surface of the substrate and a second opening approaching the second surface of the substrate;
a plurality of conductive members electrically connected to the trace layer and arranged in the through holes respectively, wherein at least one of the conductive members defines a revealed portion protruding from the second opening of a corresponding one of the through holes;
a plurality of functional elements arranged on the first surface of the substrate and electrically connected with one or ones of the conductive members through the trace layer; and
a protection member arranged on the first surface of the substrate and covering one or ones of the functional elements;
wherein, a ratio of a measured area of the first opening to a measured area of the revealed portion of the conductive member arranged therein is no less than 1/4;
wherein, one of the functional elements electrically connects with the circuit trace layer through connections between ones of the conductive members and the circuit trace layer.
